(19) United States
(12) Patent Application Publication
(10) Pub. No.: US 2023/0192014 A1
(43) Pub. Date: Jun. 22, 2023

(54) WIRE HARNESS UNIT

(71) Applicants: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(72) Inventors: Takeo MARUCHI, Yokkaichi-shi (JP); Masanori KUWAHARA, Yokkaichi-shi (JP); Yuichi KIMOTO, Yokkaichi-shi (JP)

(73) Assignees: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(21) Appl. No.: 18/008,296

(22) PCT Filed: May 27, 2021
(86) PCT No.: PCT/JP2021/020241

§ 371 Date: Dec. 5, 2022

(30) Foreign Application Priority Data
Jun. 8, 2020 (JP) 2020-099405

(51) Int. Cl. B60R 16/02; H02G 3/03; H02G 3/04; H01B 7/42

(52) U.S. Cl. CPC B60R 16/0215; H01B 7/42; H02G 3/03; H02G 3/04

(57) ABSTRACT

A wire harness unit including: a conductive path for conducting electricity between in-vehicle devices, the conductive path including a conductive hollow tubular conductor, a flexible conductor that is more flexible than the tubular conductor, and a terminal; and a cooling tube through which a coolant is flowable for cooling the conductive path and that is separate from the tubular conductor, wherein: the tubular conductor is more rigid than the cooling tube, the flexible conductor includes a first end that is electrically connected to the tubular conductor, and a second end that is electrically connected to the terminal, and the cooling tube extends through the tubular conductor, and further extends through the flexible conductor between the first end and the second end of the flexible conductor.

### BACKGROUND

The present disclosure relates to a wire harness unit.

Conventionally, wire harnesses installed in vehicles such as hybrid cars and electric cars electrically connect a plurality of electrical devices to each other. Also, in electric cars, vehicles and ground facilities are connected to each other by a wire harness, and a power storage device installed in the vehicle is charged by the ground facility. As a result of a voltage supplied through the wire harness being high, the amount of heat generated by the wire harness is increased. For this reason, configurations for cooling wire harnesses have been proposed.

For example, JP 2019- 115253A discloses a wire harness provided with a coated wire, an inner tube that covers the coated wire, and an outer tube that covers the inner tube with a predetermined space therebetween, in which a circulation path for a coolant is formed between the inner tube and the outer tube. The circulation path is formed by inner and outer tubes that are separate from the coated wire, and the coated wire is disposed radially inward of the circulation path.

### SUMMARY

Incidentally, in the wire harness disclosed in JP 2019-115253A, the circulation path (a path along which the coolant flows) is disposed outside the coated wire, and thus the coolant is far from the central portion of the coated wire, which is the heat source. Accordingly, there is room for improvement in terms of cooling efficiency of the coated wire.

An exemplary aspect of the disclosure provides a wire harness unit capable of improving cooling efficiency.

A wire harness unit that is an aspect of the present disclosure includes a conductive path for conducting electricity between in-vehicle devices, and a cooling portion for cooling the conductive path, and the conductive path includes a conductive hollow tubular conductor, the cooling portion includes a cooling tube through which a coolant is flowable and that is separate from the tubular conductor, the tubular conductor is more rigid than the cooling tube, and the cooling tube extends through the tubular conductor.

According to a wire harness unit that is an aspect of the present disclosure, cooling efficiency can be improved.

### BRIEF DESCRIPTION OF THE DRAWINGS

FIG. 1 is a schematic diagram showing a vehicle in which a wire harness unit according to an embodiment is routed.

FIG. 2 is a schematic diagram of the wire harness unit.

FIG. 3 is a partial cross sectional view showing an overview of the wire harness unit.

FIG. 4 is a cross sectional view of the wire harness unit.

FIG. 5 is a diagram illustrating connection between a tubular conductor, a flexible conductor, and a terminal.

### DETAILED DESCRIPTION OF EMBODIMENTS

### Description of Embodiments of Disclosure

First, aspects of the present disclosure will be listed and described.

A wire harness unit according to the present includes a conductive path for conducting electricity between in-vehicle devices, and a cooling portion for cooling the conductive path, and the conductive path includes a conductive hollow tubular conductor, the cooling portion includes a cooling tube through which a coolant is flowable and that is separate from the tubular conductor, the tubular conductor is more rigid than the cooling tube, and the cooling tube extends through the tubular conductor.

According to this configuration, as a result of the cooling tube through which the coolant flows extending through the tubular conductor, the coolant can be supplied to the inside of the tubular conductor. For this reason, the tubular conductor can be cooled from the inside, thereby making it possible to improve cooling efficiency.

[2] It is preferable that an outer circumferential surface of the cooling-tube is in contact with an inner circumferential surface of the tubular conductor.

According to this configuration, as a result of the cooling tube through which the coolant flows being in contact with the inner circumferential surface of the tubular conductor, the tubular conductor (conductive path) can be further cooled.

[3] It is preferable that the conductive path includes a flexible conductor and a terminal, the flexible conductor includes a first end portion that is electrically connected to the tubular conductor, and a second end portion that is electrically connected to the terminal, and the flexible conductor is more flexible than the tubular conductor.

According to this configuration, due to the end portion of the tubular conductor being connected to the flexible conductor, dimensional tolerance of the conductive path can be absorbed. Further, this configuration is a counter measure against swinging generated while a vehicle is travelling.

It is preferable that the tubular conductor is longer than the flexible conductor.

According to this configuration, since the section where the tubular conductor is in contact with the cooling tube is long, the tubular conductor can be further cooled.

It is preferable that the wire harness unit further includes an electromagnetic shield member for covering at least a portion of the cooling tube and the tubular conductor, and the electromagnetic shield member is a braided member formed by braiding metal strands, and the cooling tube extends through the braided member.

According to this configuration, both the shielding properties for suppressing electromagnetic noise radiation from the conductive path and an improvement in the ease of assembly of the cooling portion can be achieved.

It is preferable that the wire harness unit further includes an exterior member for covering at least a portion of the cooling tube and the conductive path, and the exterior member includes a tubular exterior member and a grommet connected to an end portion of the tubular exterior member, and the cooling tube extends through the grommet.

According to this configuration, since the cooling tube extends through the grommet and is led out to the outside, a decrease in the water blocking properties of the wire harness unit can be suppressed.

### Description of Embodiments of Disclosure

Specific examples of a wire harness unit according to the present disclosure will be described below with reference to the drawings. Note that, in the drawings, parts of the configurations may be shown in an exaggerated or simplified manner for convenience of description. Moreover, dimensional ratios of various portions may be different from actual dimensional ratios. “Parallel” and “orthogonal” in the present specification include not only being exactly parallel and orthogonal but also approximately parallel and orthogonal within a range in which the operation and effects of the present embodiment can be achieved. The present disclosure is not limited to the embodiments disclosed herein, but is defined by the claims, and intended to include all modifications within the meaning and the scope equivalent thereof.

### Overview Configuration of Wire Harness Unit 10

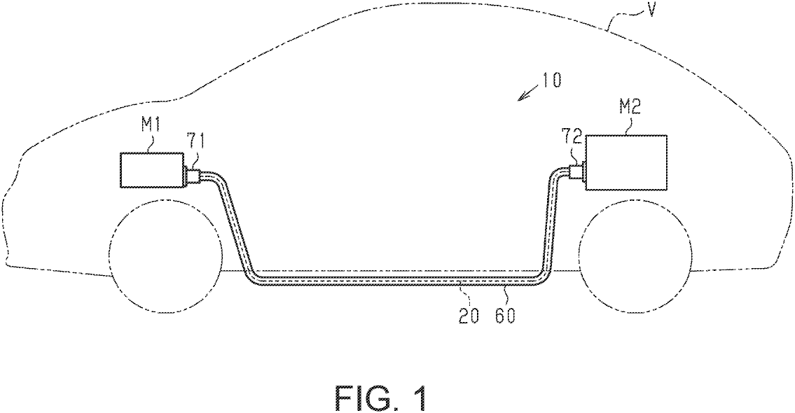

A wire harness unit 10 shown in FIG. 1 electrically connects two in-vehicle devices installed in a vehicle V. The vehicle V is, for example, a hybrid car, an electric car, or the like. The wire harness unit 10 includes conductive paths 20 for electrically connecting an in-vehicle device M1 and an in-vehicle device M2, and an exterior member 60 for covering the conductive paths 20. The conductive paths 20 are routed, for example, from the in-vehicle device M1 to the in-vehicle device M2 so that portions thereof in a lengthwise direction pass under the floor of the vehicle V. With regard to examples of the in-vehicle device M1 and the in-vehicle device M2, the in-vehicle device M1 is an inverter installed toward the front side of the vehicle V, and the in-vehicle device M2 is a high-voltage battery installed on the rear side of the vehicle V relative to the in-vehicle device M1. The in-vehicle device M1 serving as an inverter is connected to a motor (not shown) for driving the wheels serving as a motive power source for causing the vehicle to travel, for example. The inverter generates AC power from DC power from the high-voltage battery, and supplies the AC power to the motor. The in-vehicle device M2, which is a high-voltage battery, is a battery capable of supplying a voltage of at least 100 V, for example. In other words, the conductive paths 20 of the present embodiment constitute a high-voltage circuit that enables high-voltage exchange between the high-voltage battery and the inverter.

### Overview Configuration of Wire Harness Unit 10

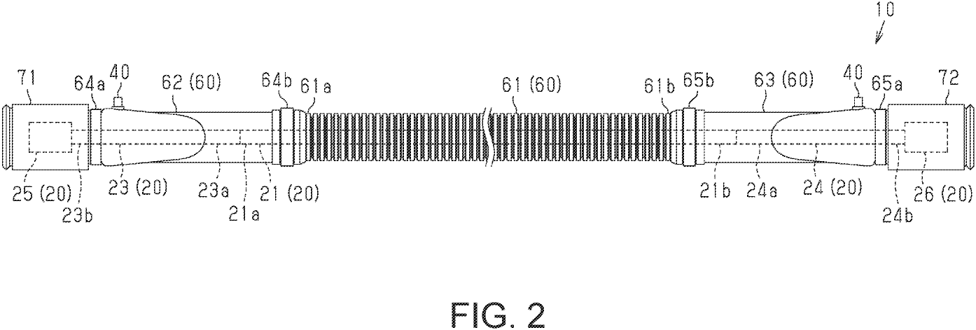

As shown in FIGS. 2, 3, and 4, the wire harness unit 10 includes two conductive paths 20, two cooling tubes 40, an electromagnetic shield member 50 (electromagnetic shield), an exterior member 60 (exterior tube), and connectors 71 and 72.

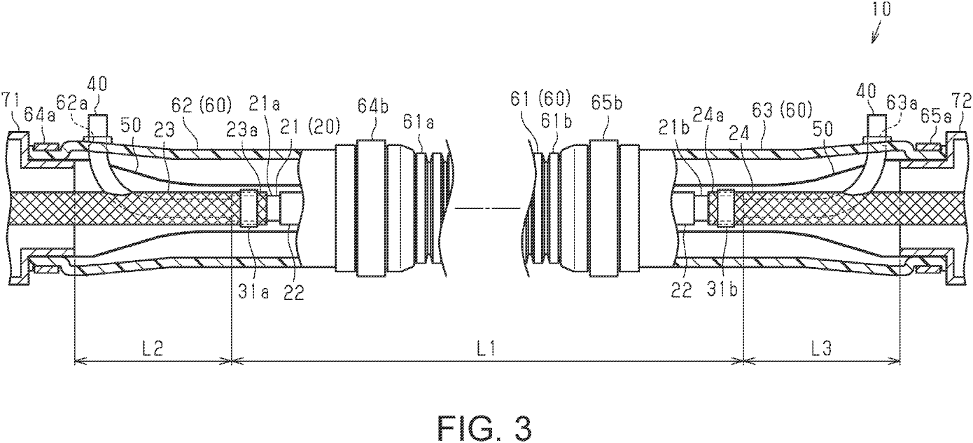

As shown in FIGS. 3, 4, and 5, each conductive paths 20 include tubular conductors 21, insulating coatings 22, flexible conductors 23 and 24, and terminals 25 and 26.

The tubular conductors 21 are conductive and has a hollow structure. The tubular conductors 21 are made of metal, for example, and have high shape holding properties. In other words, the tubular conductors 21 can retain its shape. The material for the tubular conductors 21 is a metal material such as a copper-based material or an aluminum-based material. The tubular conductors 21 are formed in a shape conforming to a routing path of the wire harness unit 10 shown in FIG. 1. The tubular conductors 21 are bent using a pipe bender (pipe bending device).

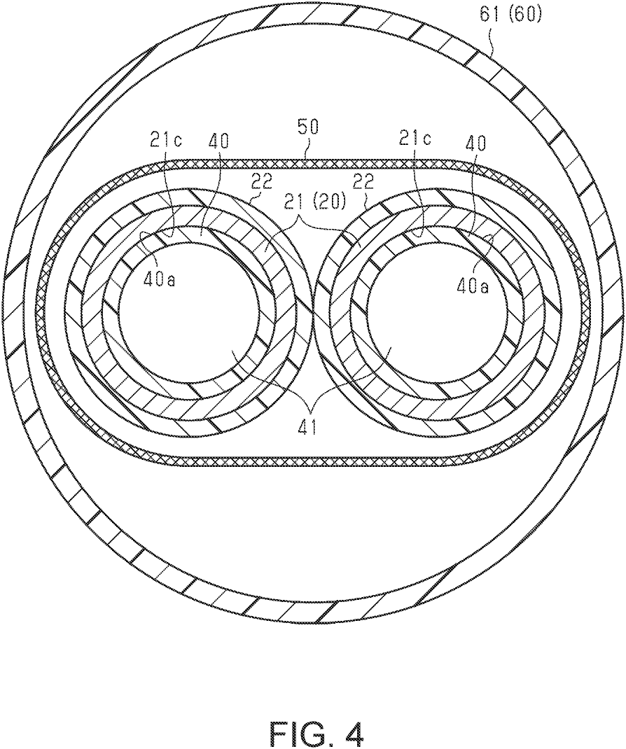

FIG. 4 is a cross-sectional view of the wire harness u .nit 10 taken along a plane orthogonal to the lengthwise direction of the wire harness unit 10. In FIG. 4, the lengthwise direction of the tubular conductors 21 is the front-back direction of the sheet plane of FIG. 4. The cross-sectional shape of the tubular conductors 21 taken along a plane that is vertical to the lengthwise direction of the tubular conductors 21, that is, a direction in which the tubular conductors 21 extends and that is the axial direction of tubular conductors 21 (i.e., a lateral cross-sectional shape) is annular, for example. Note that, the cross sectional shape of the tubular conductors 21 can be any shape. Also, with respect to the cross sectional shape of the tubular conductors 21, the shapes of the outer circumference and the inner circumference may be different from each other. Also, cross sectional shapes of the tubular conductors 21 in the lengthwise direction may be different from each other.

The insulating coatings 22 cover the entirety of the outer circumferential surfaces of the tubular conductors 21 in the circumferential direction, for example. The insulating coatings 22 are constituted by an insulating material such as a synthetic resin. Examples of the material for the insulating coatings 22 include silicone resin, a synthetic resin whose main component is a polyolefin resin such as cross-linked polyethylene or cross-linked polypropylene, and the like. A single kind of material, or two or more kinds of materials can be used in combination as appropriate, for the insulating coatings 22. The insulating coatings 22 can be formed by performing extrusion molding (extrusion coating) on the tubular conductors 21, for example.

As shown in FIG. 3, each tubular conductor 21 includes a first end portion 21a and a second end portion 21b that are two end portions of the corresponding tubular conductor 21 in the lengthwise direction. The first end portion 21a and the second end portion 21b are exposed from the corresponding insulating coating 22.

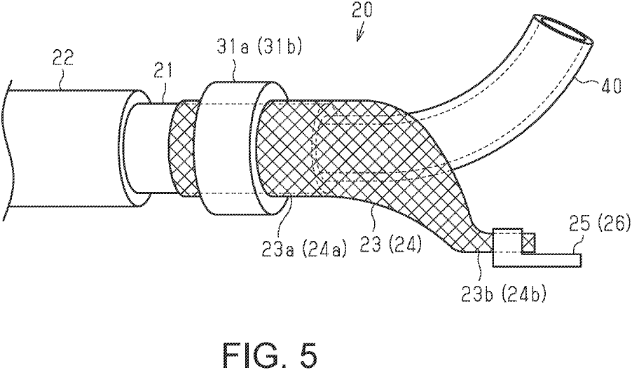

As shown in FIGS. 3 and 5, end portions on one side of the flexible conductors 23 and 24 are respectively connected to the first end portions 21a and the second end portions 2 1b, and end portions on the other side of the flexible conductors 23 and 24 are respectively connected to the terminals 25 and 26 shown in FIG. 2. Specifically, each flexible conductor 23 includes a first end portion 23a that is electrically connected to the first end portion 21a of the corresponding tubular conductor 21 and a second end portion 23b that is electrically connected to the terminal 25 shown in FIGS. 2 and 5. Each flexible conductor 24 includes a first end portion 24a that is electrically connected to the second end portion 21b of the corresponding tubular conductor 21 and a second end portion 24b that is electrically connected to the terminal 26 shown in FIG. 2.

The flexible conductors 23 and 24 are conductors that are more flexible than the tubular conductors 21. The flexible conductors 23 and 24 of the present embodiment are formed in a tubular shape. The flexible conductors 23 and 24 are braided wires formed by braiding conductive wire strands into a tubular shape. The material for the wire strands is a metal material such as a copper-based material or an aluminum-based material.

As shown in FIG. 3, the first end portions 21a of the tubular conductors 21 are disposed inside the tubular first end portions 23a of the flexible conductors 23. In other words, the first end portions 23a of the tubular flexible conductors 23 cover the first end portions 21a of the tubular conductors 21. A fastening band 31a is attached to the outer circumference side of each flexible conductor 23. Each flexible conductor 23 is crimped to the outer circumferential surface of each tubular conductor 21 by the fastening band 31a. Each first end portion 23a of the flexible conductor 23 is electrically connected to the outer circumferential surface of the first end portion 21a of the corresponding tubular conductor 21 using the fastening band 31a. Note that the tubular conductors 21 and the flexible conductors 23 may also be connected to each other through welding such as ultrasonic welding.

The second end portions 21b of the tubular conductors 21 are disposed inside the tubular first end portions 24a of the flexible conductors 24. In other words, the first end portions 24a of the tubular flexible conductors 24 cover the second end portions 21b of the tubular conductors 21. Each fastening band 31b is attached to the outer circumference side of the flexible conductors 24. Each flexible conductor 24 is crimped to the outer circumferential surface of the corresponding tubular conductor 21 using the fastening band 31b. Each first end portion 24a of the flexible conductor 24 is electrically connected to the outer circumferential surface of the second end portion 21b of the corresponding tubular conductor 21 by the fastening band 31b. Note that the flexible conductors 24 and the tubular conductors 21 may be connected to each other through welding such as ultrasonic welding.

FIG. 5 is an illustrative diagram showing connection between the tubular conductor, the flexible conductors, and the terminals. Note that, in FIG. 5, the members of the conductive paths 20 shown on the left side of FIGS. 2 and 3 are indicated by reference signs without parentheses, and the members shown on the right side of FIGS. 2 and 3 are indicated by reference signs in parentheses.

Each terminal 25 is held by a connector 71 shown in FIGS. 1 and 2, and connected to the in-vehicle device M1 Each terminal 25 is connected to the second end portion 23b of the flexible conductor 23. For example, each terminal 25 includes a pair of crimping pieces, with which the terminal 25 is crimped to the second end portion 23b of the flexible conductor 23. Each terminal 26 is held by the connector 72 shown in FIGS. 1 and 2, and connected to the in-vehicle device M2. Each terminal 26 is connected to the second end portion 24b of the flexible conductor 24. For example, each terminal 26 includes a pair of crimping pieces, with which the terminal 26 is crimped to the second end portion 24b of the flexible conductor 24.

As shown in FIGS. 3 and 4, the cooling tubes 40 extend through the tubular conductors 21. The cooling tubes 40 are hollow. The cooling tubes 40 are more flexible than the tubular conductors 21. In other words, the tubular conductors 21 are more rigid than the cooling tubes 40.

As shown in FIG. 4, in the present embodiment, outer circumferential surfaces 40a of the cooling tubes 40 are respectively in contact with inner circumferential surfaces 21c of the tubular conductors 21. Note that an adhesive or a resin material such as a pressure-sensitive adhesive may be interposed between the outer circumferential surfaces 40a of the cooling tubes 40 and the inner circumferential surfaces 21c of the tubular conductors 21. A material that has excellent heat conductivity can be used as an interposing resin material. The material for the cooling tubes 40 is a flexible resin material such as PP (polypropylene), PVC (polyvinyl chloride), or cross-linked PE (polyethylene resin).

A coolant 41 is supplied to the inside of the cooling tubes 40. The coolant 41 may be a liquid such as water and antifreeze solution, or a fluid such as a gas, or an air-liquid two-phase flow in which a gas and a liquid are mixed. The coolant 41 is supplied by a pump (not shown). The cooling tubes 40 are a part of a circulation path through which the coolant 41 is circulated. The circulation path includes the above-described pump and a heat dissipating portion, for example. The pump pressurizes and feeds the coolant 41 to the cooling tubes 40. The coolant 41 supplied to the cooling tubes 40 performs heat-exchange with the tubular conductors 21 located outside of the cooling tubes 40. The heat dissipating portion cools the coolant 41 by dissipating heat from the coolant 41, of which the temperature has risen as a result of the heat exchange, to the outside. The cooled coolant 41 is pressurized and fed again to the cooling tubes 40 by the pump. The cooling tubes 40 constitute a cooling portion for cooling the tubular conductors 21 using the coolant 41 circulated in this manner.

As shown in FIGS. 3 and 4, the electromagnetic shield member 50 covers two conductive paths 20. The electromagnetic shield member 50 is a braided member formed by braiding metal strands into a tubular shape. The electromagnetic shield member 50 has shielding properties. Also, the electromagnetic shield member 50 is flexible. As shown in FIG. 3, one end of the electromagnetic shield member 50 is connected to the connector 71, and the other end of the electromagnetic shield member 50 is connected to the connector 72. Accordingly, the electromagnetic shield member 50 covers the entire length of the conductive paths 20 that transmit a high voltage. In this manner, the radiation of electromagnetic noise originating from the conductive paths 20 to the outside is suppressed.

The exterior member 60 covers the conductive paths 20. The above-described cooling tubes 40 respectively extend through the tubular conductors 21 of the conductive paths 20. Accordingly, the exterior member 60 covers the conductive paths 20 and at least a portion of the cooling tubes 40.

The exterior member 60 includes a tubular exterior member 61, and grommets 62 and 63 respectively connected to a first end portion 61a and a second end portion 61b of the tubular exterior member 61.

The tubular exterior member 61 covers a portion of the outer circumferences of the tubular conductors 21 in the lengthwise direction, for example. The tubular exterior member 61 is formed in a tubular shape in which the two ends of each of the tubular conductors 21 in the lengthwise direction are open, for example. The tubular exterior member 61 surrounds the entirety of the outer circumferences of the plurality of tubular conductors 21 in the circumferential direction, for example. The tubular exterior member 61 of the present embodiment is formed in a cylindrical shape. The tubular exterior member 61 has a bellows structure in which, for example, annular protruding portions and annular recessed portions are alternately arranged along the axis direction (lengthwise direction) thereof in which the central axial line of the tubular exterior member 61 extends. Examples of the material for the tubular exterior member 61 include a conductive resin material and a non-conductive resin material. Examples of the resin material include a synthetic resin such as polyolefin, polyamide, polyester, and ABS resin. The tubular exterior member 61 of the present embodiment is a corrugated tube made of a synthetic resin.

The grommet 62 is formed in a substantially tubular shape. The grommet 62 is made of rubber, for example. The grommet 62 spans between the connector 71 and the tubular exterior member 61. The grommet 62 is fastened and fixed to the outer surface of the connector 71 by a fastening band 64a so as to be in close contact therewith. Also, the grommet 62 is fastened and fixed to the outer side of the first end portion 61a of the tubular exterior member 61 by a fastening band 64b so as to be in close contact therewith. Through holes 62a extending through the grommet 62 are formed in the grommet 62. The through holes 62a bring the inside and the outside of the grommet 62 into communication.

In the present embodiment, two through holes 62a are formed in the grommet 62, and the cooling tubes 40 are respectively passed through the through holes 62a. The through holes 62a come in close contact with the outer circumferential surfaces of the cooling tubes 40 which are respectively passed through the through holes 62a. As shown in FIG. 3, the cooling tubes 40 extend through the flexible conductor 23 and the electromagnetic shield member 50, and are led out to the outside of the grommet 62 through the through holes 62a of the grommet 62.

The grommet 63 is formed in a substantially tubular shape. The grommet 63 is made of rubber, for example. The grommet 63 spans between the connector 72 and the tubular exterior member 61. The grommet 63 is fastened and fixed to the outer surface of the connector 72 by a fastening band 65a so as to be in close contact therewith. Also, the grommet 63 is fastened and fixed to the outer side of the second end portion 61b of the tubular exterior member 61 by a fastening band 65b so as to be in close contact therewith. Through holes 63a extending through the grommet 63 are formed in the grommet 63. Through holes 63a bring the inside and the outside of the grommet 63 into communication.

In the present embodiment, the two through holes 63a are formed in the grommet 63, and the cooling tubes 40 are respectively passed through the through holes 63a. The through holes 63a come in close contact with the outer circumferential surfaces of the cooling tubes 40 which are respectively passed through the through holes 63a. As shown in FIG. 3, the cooling tubes 40 extend through the flexible conductor 24 and the electromagnetic shield member 50, and are led out to the outside of the grommet 63 through the through holes 63a of the grommet 63.

### Operation

Next, operation of the wire harness unit 10 of the present embodiment will be described.

The wire harness unit 10 includes the conductive paths 20 that conduct electricity between the in-vehicle devices M1 and M2, and the cooling tubes 40 constituting the cooling portion that cools the conductive paths 20. The conductive paths 20 include the conductive hollow tubular conductors 21, and the cooling tubes 40, which are separate from the tubular conductors 21, allow the coolant 41 to flow therethrough. The tubular conductors 21 are more rigid than the cooling tubes 40. Also, the cooling tubes 40 extend through the tubular conductors 21.

The coolant 41 is supplied to the cooling tubes 40. The tubular conductors 21 are cooled through heat exchange between the coolant 41 supplied to the cooling tubes 40 and the tubular conductors 21. In this manner, the tubular conductors 21 can be cooled from the inside.

Compared to a braided wire formed by twisting together a plurality of metal strands having the same cross sectional area and a single core wire having a solid structure, the tubular conductors 21 have a larger outer circumference. In other words, the tubular conductors 21 have a larger area on the outer circumferential side compared to a braided wire and a single core wire. Accordingly, since heat can be dissipated outward from a larger area, heat dissipation properties can be improved.

The conductive paths 20 include the flexible conductors 23 and 24 respectively connected to the first end portions 21a and the second end portions 21b of the tubular conductors 21. The flexible conductors 23 and 24 are more flexible than the tubular conductors 21. Accordingly, dimensional tolerance of the conductive paths 20 can be absorbed. Also, when the vehicle V vibrates, positional deviation between the parts connected to two ends of the flexible conductors 23 and 24 due to the vibration can be absorbed. In the present embodiment, positional deviation between the tubular conductors 21 and the connectors 71 and 72, that is, between the tubular conductors 21 and the in-vehicle devices M1 and M2 can be absorbed. Accordingly, loads applied to the connectors 71 and 72 and the terminals 25 and 26 can be reduced.

Also, as shown in FIG. 3, the length L1 of the tubular conductors 21 is greater than the lengths L2 and L3 of the flexible conductors 23 and 24. The lengths L2 and L3 of the flexible conductors 23 and 24 are lengths indicating the range in which the conductive paths 20 can be bent utilizing the flexibility of the flexible conductors 23 and 24. In the present embodiment, the lengths L2 and L3 are the distance between the tubular conductors 21 and the connector 71 and the distance between the tubular conductors 21 and the connector 72, respectively. Accordingly, the section of the tubular conductors 21 through which the cooling tubes 40 extend is long, that is, the section in which the cooling tubes 40 and the tubular conductors 21 are in contact with each other and exchange heat is long, and thus the tubular conductors 21 can be further cooled. Note that the lengths L2 and L3 of the flexible conductors 23 and 24 can be equal to or different from each other.

The flexible conductors 23 and 24 of the present embodiment are braided members formed by braiding metal strands into a tubular shape. For this reason, the cooling tubes 40 can be led out from the flexible conductors 23 and 24 at intermediate positions of the flexible conductors 23 and 24. In this manner, the cooling tubes 40 can be readily led out to the outside of the wire harness unit 10, and constituent members for circulating the coolant 41 can be readily connected to the cooling tubes 40.

The electromagnetic shield member 50 covers the two conductive paths 20. The electromagnetic shield member 50 is a braided member formed by braiding metal strands into a tubular shape. For this reason, radiation of the electromagnetic noise originating from the conductive paths 20 to the outside can be suppressed. Also, for this reason, the cooling tubes 40 can be led out from the electromagnetic shield member 50 at intermediate positions of the electromagnetic shield member 50. Thus, the cooling tubes 40 can be readily led out to the outside of the wire harness unit 10, and constituent members for circulating the coolant 41 can be readily connected to the cooling tubes 40.

The wire harness unit 10 includes the exterior member 60 for covering at least a portion of the cooling tubes 40 and the conductive paths 20. The exterior member 60 includes a tubular exterior member 61, and grommets 62 and 63 respectively connected to a first end portion 61a and a second end portion 61b of the tubular exterior member 61. The cooling tubes 40 extend through the grommets 62 and 63. In this manner, since the cooling tubes 40 extend through the grommets 62 and 63 so as to be led out to the outside of the wire harness unit 10, degradation of the water blocking properties of the wire harness unit 10 can be suppressed.

As described above, according to the present embodiment, the following effects are achieved.

The wire harness unit 10 includes the conductive paths 20 for conducting electricity between the in-vehicle devices M1 and M2 and the cooling tubes 40 constituting the cooling portion for cooling the conductive paths 20. The conductive paths 20 each include a conductive hollow tubular conductor 21, and the cooling tubes 40, which are separate from the tubular conductors 21, allow the coolant 41 to circulate therethrough. The tubular conductors 21 are more rigid than the cooling tubes 40. Also, the cooling tubes 40 respectively extend through the tubular conductors 21.

The coolant 41 is supplied to the cooling tubes 40. The tubular conductors 21 are cooled through heat exchange between the coolant 41 supplied to the cooling tubes 40 and the tubular conductors 21. In this manner, the tubular conductors 21 can be cooled from the inside, and cooling efficiency can be improved.

(2) Compared to a twisted wire formed by twisting together a plurality of metal strands having the same cross sectional area and a single core wire having a solid structure, the tubular conductors 21 have a greater outer circumference. In other words, each tubular conductor 21 has a larger area on the outer circumferential side compared to a twisted wire and a single core wire. Accordingly, since heat can be dissipated outward from a larger area, heat dissipation properties can be improved.

(3) The conductive paths 20 include the flexible conductors 23 and 24 respectively connected to the first end portions 21a and the second end portions 21b of each tubular conductors 21. The flexible conductors 23 and 24 are more flexible than the tubular conductors 21. Accordingly, dimensional tolerance of the conductive paths 20 can be absorbed. Also, when the vehicle V vibrates, positional deviation between the parts connected to two ends of the flexible conductors 23 and 24 due to the vibration can be absorbed. In the present embodiment, the positional deviation between the tubular conductors 21 and the connectors 71 and 72, that is, between the tubular conductors 21 and the in-vehicle devices M1 and M2 can be absorbed. Accordingly, loads applied to the connectors 71 and 72 and the terminals 25 and 26 can be reduced.

(4) The length L1 of the tubular conductors 21 is greater than the lengths L2 and L3 of the flexible conductor 23 and 24. Accordingly, the tubular conductors 21 through which the cooling tubes 40 extend is long, that is, the section in which the cooling tubes 40 and the tubular conductors 21 are in contact with each other and exchange heat can be long, and thus the tubular conductors 21 can be further cooled.

(5) The flexible conductors 23 and 24 are braided members formed by braiding metal strands into a tubular shape. For this reason, the cooling tubes 40 can be led out from the flexible conductors 23 and 24 at intermediate positions of the flexible conductors 23 and 24. In this manner, the cooling tubes 40 can be readily led out to the outside of the wire harness unit 10, and constituent members for circulating the coolant 41 can be readily connected to the cooling tubes 40.

(6) The electromagnetic shield member 50 covers the two conductive paths 20. The electromagnetic shield member 50 is a braided member formed by braiding metal strands into a tubular shape. For this reason, radiation of the electromagnetic noise originating from the conductive paths 20 to the outside can be suppressed. Also, for this reason, the cooling tubes 40 can be led out from the electromagnetic shield member 50 at intermediate positions of the electromagnetic shield member 50. In this manner, the cooling tubes 40 can be readily led out to the outside of the wire harness unit 10, and constituent members for circulating the coolant 41 can be readily connected to the cooling tubes 40.

(7) The wire harness unit 10 includes the exterior member 60 for covering at least a portion of the cooling tubes 40 and the conductive paths 20. The exterior member 60 includes a tubular exterior member 61, and grommets 62 and 63 respectively connected to the first end portion 61a and the second end portion 61b of the tubular exterior member 61. The cooling tubes 40 extend through the grommets 62 and 63. In this manner, since the cooling tubes 40 extends through the grommets 62 and 63 so as to be led out to the outside of the wire harness unit 10, degradation of the water blocking properties of the wire harness unit 10 can be suppressed.

### Variations

The present embodiment can be modified and implemented as follows. The present embodiment and the variations below may be implemented in combination with each other as long as no technical contradictions arise.

• A configuration is also possible in which a plurality of the cooling tubes 40 are connected to each other to allow the coolant 41 to circulate.

For example, on the side of the wire harness unit 10 on which the coolant 41 is supplied, one cooling tube is connected to a cooling tube 40 shown in FIG. 3, and the coolant 41 supplied from a single cooling tube is branched into two cooling tubes 40. The branch portion of the cooling tube may be located outside or inside the grommet 62. By doing so, it is sufficient that a single cooling tube for supplying the coolant 41 is connected to the wire harness unit 10, and thus the attachment process of the wire harness unit 10 can be simplified.

Also, on the side of the wire harness unit 10 on which the coolant 41 is discharged, two cooling tubes 40 are connected to merge the coolant 41 in each of the cooling tubes 40. The merging portion of the cooling tubes may be located outside or inside the grommet 63. By doing so, it is sufficient that a single cooling tube for discharging the coolant 41 is connected to the wire harness unit 10, and thus the attachment process of the wire harness unit 10 can be simplified.
In the above embodiment, the cooling tubes 40 are led out from the grommets 62 and 63, that is, the cooling tubes 40 are passed through grommets 62 and 63. However, the cooling tubes 40 may be led out from the connectors 71 and 72. By doing so, the tubular conductors 21 and the connectors 71 and 72 can be cooled.
The electromagnetic shield member 50 of the above embodiment may be a piece of metal tape or the like.
In contrast to the above embodiment, the wire harness unit may include one or three or more conductive paths.
Twisted wires formed by twisting a plurality of metal strands together may be used as the flexible conductors 23 and 24 of the above embodiment.
In contrast to the above embodiment, the tubular flexible conductors 23 and 24 do not need to cover the tubular conductors 21. For example, the flexible conductors 23 and 24 may be electrically connected to each tubular conductor 21 by rounding the tubular flexible conductors 23 and 24 into a rod-like shape, and crimping the flexible conductors 23 and 24 to the outer circumferential surface of the tubular conductors 21 using the fastening bands 31a and 31b. In this case, it is not necessary to lead out the cooling tubes 40 that extend through the tubular conductors 21 from the intermediate portions of the flexible conductors 23 and 24, thereby facilitating assembly.
In contrast to the above embodiment, a configuration is also possible in which, for example, the tubular flexible conductors 23 and 24 are formed in a sheet-like shape, and the flexible conductors 23 and 24 are respectively wrapped around the outer circumferential surfaces of the tubular conductors 21 in the manner of a sushi roll, and crimped to the tubular conductors 21 using the fastening bands 31a and 31b. The flexible conductors 23 and 24 may or may not be wrapped around the cooling tubes 40 that extend through the tubular conductors 21. If the flexible conductors 23 and 24 are wrapped around the cooling tubes 40, the cooling tubes 40 can be readily drawn out from a gap between the flexible conductors 23 and 24 overlaid in the manner of a sushi roll.
Although the above embodiment and the variations described that the shape of the flexible conductor 23 on the connector 71 side and the shape of the flexible conductor 24 on the connector 72 side are the same, their shapes may be different from each other. For example, the flexible conductors 24 and the tubular conductors 21 may be respectively connected to each other by disposing the first end portions 21a of the tubular conductors 21 inside the tubular flexible conductors 23, connecting the flexible conductors 23 and the tubular conductors 21 to each other using the fastening bands 31a, and crimping a rod-like flexible conductors 24 to the outer circumferential surface of the tubular conductors 21 using the fastening bands 31b, respectively.
The tubular conductors 21 may have a length corresponding to the routing path of the wire harness unit 10. The tubular conductors 21 may be rigid to the extent that the length and/or thickness of the tubular conductors 21 does not change between immediately before and after the wire harness unit 10 is mounted in a vehicle.
As shown in FIGS. 2 to 4, the wire harness unit 10 according to a preferable example can include the tubular conductors 21, the cooling tubes 40, and an electromagnetic shield member 50. The tubular conductors 21 may each have a certain pipe length and two pipe opening ends. The cooling tubes 40 may have a tube length that is longer than the pipe length. The cooling tubes 40 may each include an intermediate portion that is housed in the corresponding tubular conductor 21 and extends through the tubular conductor 21 in the lengthwise direction, and two tube end portions that extend in two lengthwise directions from the tubular conductor 21 via the two pipe opening ends of the tubular conductor 21. The two tube end portions may respectively extend radially outward via gaps formed by unbraiding the metal strands of two electromagnetic shield members 50.
As shown in FIG. 4, the wire harness unit 10 according to a preferred example may include the tubular conductors 21 and the cooling tubes 40. The tubular conductors 21 may each include a pipe inner circumferential surface and a pipe inner diameter and the cooling tubes 40 may each include a tube outer circumferential surface and a tube outer diameter that matches or corresponds to the pipe inner diameter. The pipe inner circumferential surface of each tubular conductor 21 may come in contact with the tube outer circumferential surface of the cooling tube 40 over the pipe length of the tubular conductor 21 such that the pipe inner circumferential surface can or cannot move relative to the tube outer circumferential surface of the cooling tube 40. The tube outer circumferential surface of the cooling tube 40 may come in contact with the pipe inner circumferential surface of the tubular conductor 21 under frictional resistance or adhesion.

1. A wire harness unit comprising:
a conductive path for conducting electricity between in-vehicle devices, the conductive path including a conductive hollow tubular conductor, a flexible conductor that is more flexible than the tubular conductor, and a terminal; and
a cooling tube through which a coolant is flowable for cooling the conductive path and that is separate from the tubular conductor, wherein:
the tubular conductor is more rigid than the cooling tube,
the flexible conductor includes a first end that is electrically connected to the tubular conductor, and a second end that is electrically connected to the terminal, and
the cooling tube extends through the tubular conductor, and further extends through the flexible conductor between the first end and the second end of the flexible conductor.

2. The wire harness unit according to claim 1,
wherein an outer circumferential surface of the cooling tube is in contact with an inner circumferential surface of the tubular conductor.

3. The wire harness unit according to claim 1,
wherein the flexible conductor is a braided member formed by braiding conductive wire strands.

4. The wire harness unit according to claim 1,
wherein the tubular conductor is longer than the flexible conductor.

5. The wire harness unit according to claim 1, further comprising
an electromagnetic shield for covering at least a portion of the cooling tube and the tubular conductor, wherein:
the electromagnetic shield is a braided member formed by braiding metal strands, and
the cooling tube extends through the braided member.

6. The wire harness unit according to claim 1, further comprising
an exterior tube for covering at least a portion of the cooling tube and the conductive path, wherein:
the exterior tube includes a tubular exterior member and a grommet connected to an end of the tubular exterior member, and the cooling tube extends through the grommet.
